(19) United States
(12) Patent Application Publication
(10) Pub. No.: US 2026/0245644 A1
(43) Pub. Date: Aug. 20, 2026

(54) MEMORY SYSTEM AND METHOD FOR TESTING SAME

(71) Applicant: Kioxia Corporation, Tokyo (JP)

(72) Inventor: Akira YAMAGUCHI, Yokohama (JP)

(21) Appl. No.: 19/325,644

(22) Filed: Sep. 11, 2025

(30) Foreign Application Priority Data
Feb. 20, 2025 (JP) 2025-025927

(51) Int. Cl. G11C 29/12; G11C 29/36

(52) U.S. Cl. CPC G11C 29/1201; G11C 29/36; G11C 2029/3602

(57) ABSTRACT

A memory system includes a nonvolatile memory and a controller operatively coupled to the nonvolatile memory. The controller includes: a first input/output circuit configured to receive input of an access control signal for accessing the nonvolatile memory and a data control signal and output a signal based on data read from the nonvolatile memory; and a data control circuit configured to control data to be input to the nonvolatile memory and data to be output from the nonvolatile memory, based on the data control signal input from the first input/output circuit.

### CROSS-REFERENCE TO RELATED APPLICATION

This application is based upon and claims the benefit of priority from Japanese Patent Application No. 2025-025927, filed Feb. 20, 2025, the entire contents of which are incorporated herein by reference.

### FIELD

Embodiments described herein relate generally to a memory system and a method for testing the same.

### BACKGROUND

There is a memory system that includes a nonvolatile memory and a controller. One example of a memory system is a multi-chip package (MCP) in which one or more NAND flash memories and a controller chip used to control the NAND flash memories are housed in a single package.

Some memory systems are equipped with an interface used for a normal operation and an interface used during testing (see, for example, US-A-2010/0195396). Interfaces used for normal operations include high-speed interfaces conforming to standards such as Universal Flash Storage (UFS) and PCI Express (PCIe). Furthermore, in the controller, the interface used during testing includes an interface that allows access to the nonvolatile memory from an external terminal without going through the controller circuit for the nonvolatile memory and is hereinafter referred to as a “Bypass Interface (Bypass I/F)”. In a memory system having a Bypass I/F, during testing or defect analysis, a control signal is input to the memory system via the Bypass I/F from a testing apparatus such as a tester (hereinafter referred to as a “Bypass operation host”) provided outside the memory system.

Generally, command, address and data signals input from a Bypass operation host via a Bypass I/F are latched inside a controller and then output to a nonvolatile memory. Since there is a skew between these signals, when a signal is input at a high frequency, the signal cannot be transmitted correctly to the nonvolatile memory. In testing or defect analysis using a Bypass I/F (hereinafter collectively referred to as “testing”), signals need to be input to the memory system at a low frequency, and test is performed at a low speed, and therefore there is a problem in that defects that occur only when the nonvolatile memory is operating at a high speed, that is at the speed in the actual use case such as UFS and SSD product, cannot be detected.

### DESCRIPTION OF THE DRAWINGS

FIG. 1 is a block diagram of a memory system according to an embodiment.

FIG. 2A is a diagram showing a configuration example of input/output signals of a nonvolatile memory in the memory system according to the embodiment.

FIG. 2B is a diagram showing a configuration example of a data control signal of the memory system according to the embodiment.

FIG. 2C is a diagram showing a configuration example of a controller output signal of the memory system according to the embodiment.

FIG. 3 is a block diagram of a main part of the memory system according to the embodiment.

FIG. 4 is a diagram illustrating an example of an operation of the memory system according to the embodiment.

FIG. 5A is a timing chart illustrating the operation of the memory system according to the embodiment.

FIG. 5B is a timing chart illustrating the operation of the memory system according to the embodiment.

FIG. 6A is a timing chart illustrating the operation of the memory system according to the embodiment.

FIG. 6B is a timing chart illustrating the operation of the memory system according to the embodiment.

FIG. 7A is a timing chart illustrating the operation of the memory system according to the embodiment.

FIG. 7B is a timing chart illustrating the operation of the memory system according to the embodiment.

FIG. 8A is a timing chart illustrating the operation of the memory system according to the embodiment.

FIG. 8B is a timing chart illustrating the operation of the memory system according to the embodiment.

FIG. 9 is a block diagram of a memory system of a comparative example.

FIG. 10 is a block diagram of a main part of the memory system according to the comparative example.

### DETAILED DESCRIPTION

Embodiments provide a memory system and a method for testing a memory system capable of testing a nonvolatile memory at high speed using a Bypass I/F in a memory system including the nonvolatile memory and a controller.

In general, according to one embodiment, a memory system includes a nonvolatile memory and a controller operatively coupled to the nonvolatile memory. The controller includes: a first input/output circuit configured to receive input of an access control signal for accessing the nonvolatile memory and a data control signal and output a signal based on data read from the nonvolatile memory; and a data control circuit configured to control data to be input to the nonvolatile memory and data to be output from the nonvolatile memory, based on the data control signal input from the first input/output circuit.

An embodiment will be described with reference to the drawings. In the following description of the drawings, the same or similar parts are denoted by the same or similar reference numerals and the description thereof will be omitted. The drawings are schematic.

Furthermore, the embodiments described below are merely examples of devices and methods for embodying technical ideas, and do not specify the materials, shapes, structures, arrangements, etc. of each component. This embodiment can be modified in various ways within the scope of the claims.

### Embodiments

### Memory System Configuration

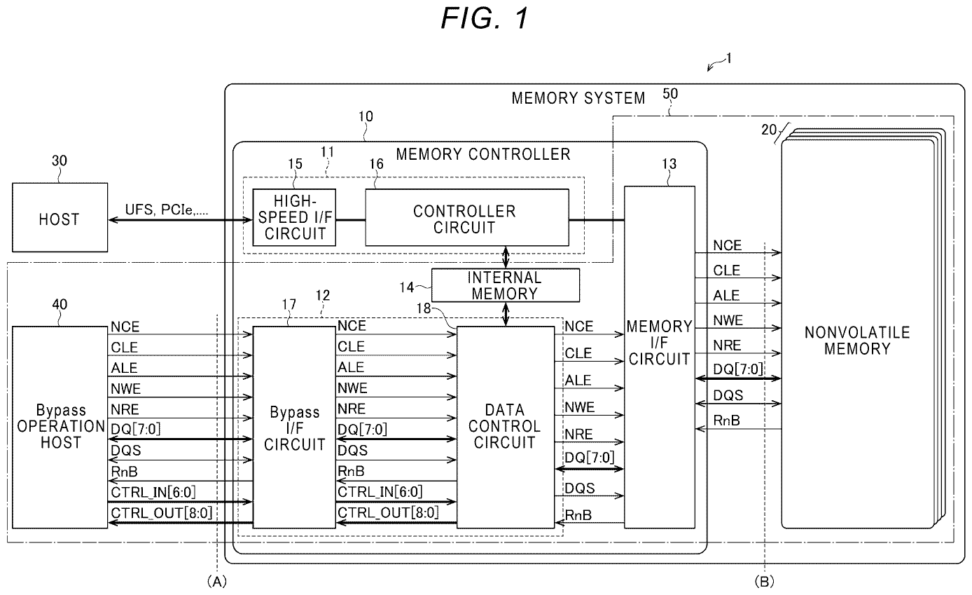

First, a memory system according to an embodiment will be described with reference to the drawings. FIG. 1 is a block diagram showing a configuration example of a memory system 1 according to the embodiment. The memory system 1 includes a memory controller 10 and a nonvolatile memory 20. The memory system 1 may be a storage device such as a storage class memory (SCM), a solid state drive (SSD), a universal flash storage (UFS), or a universal serial bus (USB) memory. The memory system 1 may be an MCP in which a nonvolatile memory 20 including one or more nonvolatile memory chips and a memory controller 10 chip are housed in a single package.

The memory system 1 can be connected to a host 30 via a high-speed interface conforming to standards such as UFS and PCIe. During normal operations of the memory system 1, the memory system 1 is connected to the host 30 as shown in FIG. 1. The host 30 may be, for example, an electronic device such as a personal computer or a mobile terminal. Unlike FIG. 1, the memory system 1 may not be connected to the host 30 when testing the memory system 1.

Further, the memory system 1 can be connected to a Bypass operation host 40. When testing the memory system 1, the memory system 1 is connected to the Bypass operation host 40 as shown in FIG. 1. The Bypass operation host 40 may be, for example, a testing device such as a tester. During normal operations of the memory system 1, unlike FIG. 1, the memory system 1 may not be connected to the Bypass operation host 40.

The memory system 1 can switch the interface and operation mode to be used between normal operation andBypass operation. The Bypass operation is also described as “testing” or “test”. Although not shown, the interface and operation mode switching can be performed by setting a register provided inside the memory controller 10, or setting by applying a voltage to a dedicated terminal of the memory system 1 when the power is turned on.

The nonvolatile memory 20 is a memory that stores data even when power is not supplied. In the following description, a case where a NAND flash memory is used as an example of the nonvolatile memory 20 will be described. However, as the nonvolatile memory 20, a storage device such as a magnetoresistive random access memory (MRAM), a ferroelectric random access memory (FeRAM), or a resistive random access memory (ReRAM) may also be used.

The memory controller 10 is a semiconductor integrated circuit configured as, for example, a System On a Chip (SoC). The memory controller 10 includes a normal operation path unit 11, a Bypass operation path unit 12, a memory I/F circuit 13, and an internal memory 14. The memory controller 10 can control the nonvolatile memory 20 as follows. The memory controller 10 can control writing to the nonvolatile memory 20 in accordance with a write request from the host 30 or the Bypass operation host 40. Furthermore, the memory controller 10 can control reading from the nonvolatile memory 20 in accordance with a read request from the host 30 or the Bypass operation host 40.

The normal operation path unit 11 includes a high-speed I/F circuit 15 and a controller circuit 16. The high-speed I/F circuit 15 can be connected to the host 30, and is connected to the controller circuit 16. The controller circuit 16 is connected to the high-speed I/F circuit 15, the memory I/F circuit 13 and the internal memory 14.

During normal operation of the memory system 1, the high-speed I/F circuit 15 performs processing conforming to the interface standard with the host 30, and outputs commands received from the host 30, data to be written, and the like to the controller circuit 16. In addition, the high-speed I/F circuit 15 transmits data read from the nonvolatile memory 20, responses from the controller circuit 16, and the like to the host 30.

The controller circuit 16 comprehensively controls each element of the memory system 1 during normal operation of the memory system 1. When receiving a command from the host 30 via the high-speed I/F circuit 15, the controller circuit 16 performs control according to the command. For example, the controller circuit 16 instructs the memory I/F circuit 13 to write data to the nonvolatile memory 20 in accordance with the command from the host 30. Furthermore, the controller circuit 16 instructs the memory I/F circuit 13 to read data from the nonvolatile memory 20 in accordance with the command from the host 30. Furthermore, when receiving a write request or a read request from the host 30, the controller circuit 16 converts the logical address received from the host 30 into a physical address indicating a storage area in the nonvolatile memory 20 and gives an instruction to the memory I/F circuit 13. Here, the controller circuit 16 will also be referred to as a first control circuit 16.

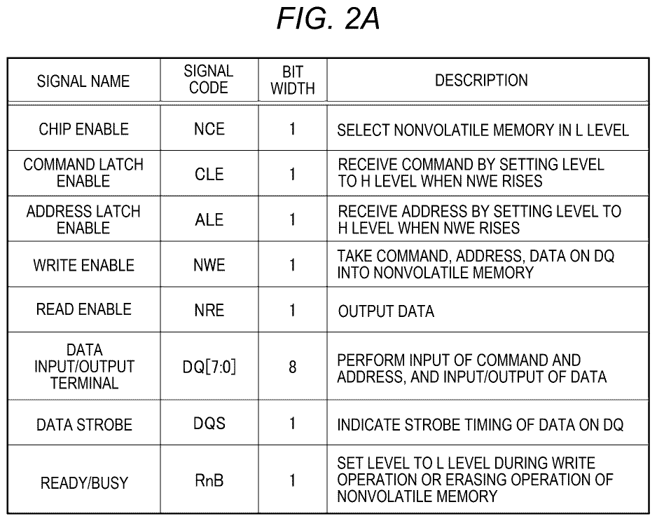

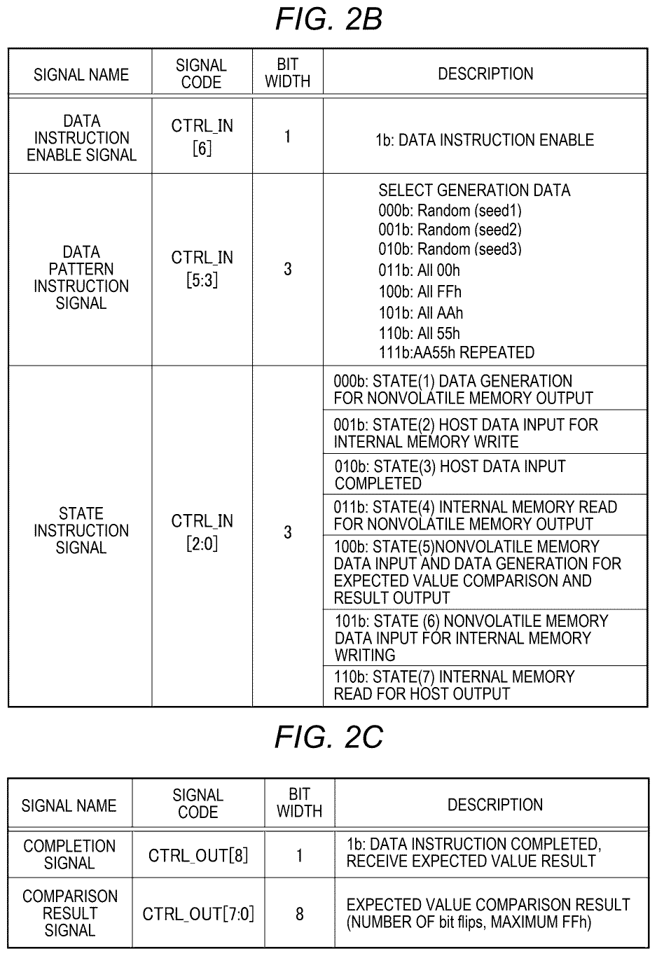

The Bypass operation path unit 12 includes a Bypass I/F circuit 17 and a data control circuit 18. The Bypass I/F circuit 17 can be connected to the Bypass operation host 40, and is connected to the data control circuit 18. The data control circuit 18 is connected to the Bypass I/F circuit 17, the memory I/F circuit 13 and the internal memory 14. Signals, which will be described later with reference to FIGS. 2A to 2C, are input and output between the Bypass operation host 40 and the Bypass I/F circuit 17, and between the Bypass I/F circuit 17 and the data control circuit 18.

Hereinafter, an operation using the Bypass I/F circuit 17 when testing the memory system 1 will be referred to as a “Bypass operation”. During Bypass operation, the Bypass I/F circuit 17 performs processing conforming to the interface standard with the Bypass operation host 40. Then, the Bypass I/F circuit 17 outputs commands received from the Bypass operation host 40, data to be written, and the like to the data control circuit 18. In addition, the Bypass I/F circuit 17 transmits data read from the nonvolatile memory 20, responses from the data control circuit 18, and the like to the Bypass operation host 40. The detailed operation of the Bypass I/F circuit 17 will be described later with reference to FIGS. 2A to 8B.

As described above, the memory system 1 can input and output signals from and to the outside of the memory system 1 by using two types of interfaces, that is, the Bypass I/F circuit 17 and the high-speed I/F circuit 15. The high-speed I/F circuit 15 can operate at a higher speed than the Bypass I/F circuit 17. Here, the Bypass I/F circuit 17 is also referred to as a first input/output circuit 17, and the high-speed I/F circuit 15 is also referred to as a second input/output circuit 15. As described above, the switching from normal operation to Bypass operation can be performed by setting a register provided inside the memory controller 10, or setting by applying a voltage to a dedicated terminal of the memory system 1 when the power is turned on.

During the Bypass operation of the memory system 1, the data control circuit 18 controls input and output of data between the Bypass operation host 40, the Bypass operation path unit 12, the memory I/F circuit 13, the internal memory 14, and the nonvolatile memory 20. The detailed operation of the data control circuit 18 will be described later with reference to FIGS. 2A to 8B.

The memory I/F circuit 13 is connected to the controller circuit 16, the data control circuit 18, and the nonvolatile memory 20, and performs a write process to the nonvolatile memory 20 and a read process from the nonvolatile memory 20, based on instructions from the controller circuit 16 or the data control circuit 18. Signals, which will be described later with reference to FIG. 2A, are input and output between the data control circuit 18 and the memory I/F circuit 13, and between the memory I/F circuit 13 and the nonvolatile memory 20.

The internal memory 14 temporarily stores data received by the memory controller 10 from the host 30 or the Bypass operation host 40, data read from the nonvolatile memory 20, and the like. The detailed operation of the internal memory 14 during Bypass operation will be described later with reference to FIGS. 2A to 8B.

During normal operation of the memory system 1, data is written to the nonvolatile memory 20 as follows.

The host 30 inputs, to the memory system 1, write command, address, and data signals for the nonvolatile memory 20. The high-speed I/F circuit 15 of the memory system 1 receives the input signal and outputs it to the controller circuit 16. The controller circuit 16 instructs the memory I/F circuit 13 to write data to the nonvolatile memory 20. The input data may be temporarily stored in the internal memory 14. The memory I/F circuit 13 performs control to write input data to a memory location on the nonvolatile memory 20 designated by the controller circuit 16.

During normal operation of the memory system 1, data is read from the nonvolatile memory 20 as follows.

The host 30 inputs, to the memory system 1, read command and address signals for the nonvolatile memory 20. The high-speed I/F circuit 15 of the memory system 1 receives the input signal and outputs it to the controller circuit 16. The controller circuit 16 instructs the memory I/F circuit 13 to read data. The memory I/F circuit 13 reads data from a specified address in the nonvolatile memory 20 in accordance with an instruction from the controller circuit 16, and outputs the read data to the controller circuit 16. The read data may be temporarily stored in the internal memory 14. The controller circuit 16 outputs the read data to the host 30 via the high-speed I/F circuit 15.

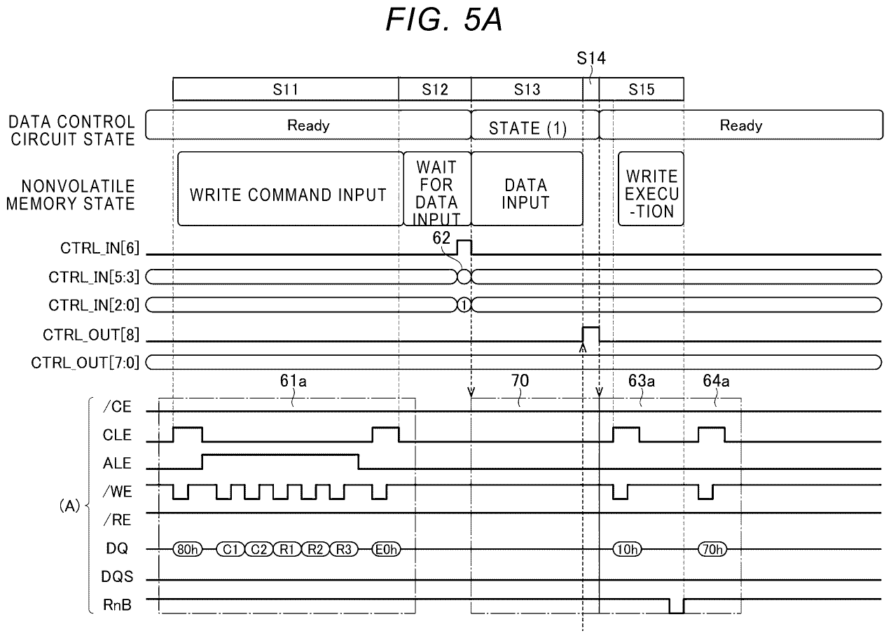

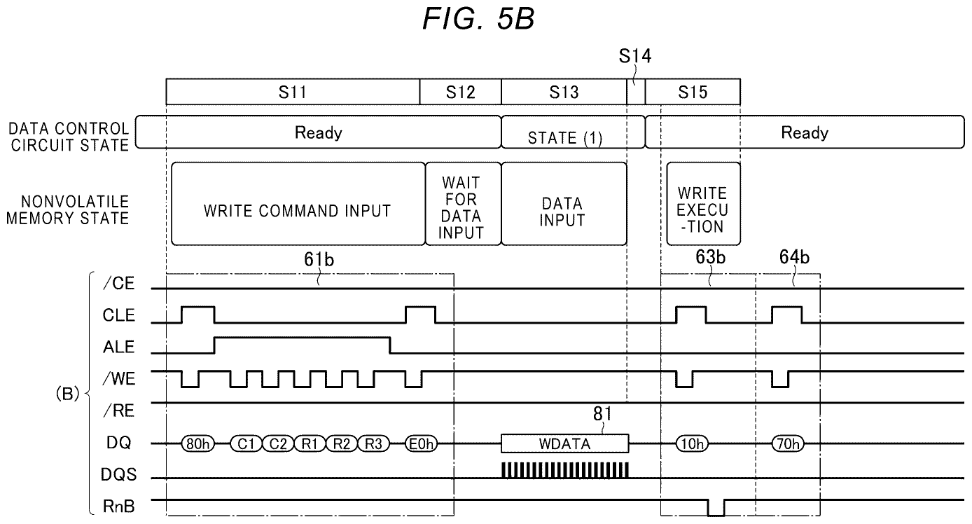

FIG. 2A is a diagram showing a configuration example of input/output signals of a nonvolatile memory in the memory system according to the embodiment. The signals shown in FIG. 2A are signals used to access the nonvolatile memory 20, and are referred to as access control signals. The access control signals in FIG. 2A are input from the Bypass operation host 40 to the memory system 1 in FIG. 1. Then, within the memory system 1, the signals are received by the Bypass I/F circuit 17, transmitted to the memory I/F circuit 13 via the data control circuit 18, and input to the nonvolatile memory 20. Furthermore, a signal output from the nonvolatile memory 20 is output to the Bypass operation host 40 via the memory I/F circuit 13, the data control circuit 18 and the Bypass I/F circuit 17. The operation of the access control signal of FIG. 2A will be described below with reference to FIGS. 5A to 8B.

Among the access control signals shown in FIG. 2A, signals whose code begins with “N” indicate negative logic, that is, signals whose active level is L level. Here, “/” may be used instead of an “N” as the first character of the code of a negative logic signal. For example, the chip enable “NCE” may be written as “/CE”. In the timing charts shown in FIGS. 5A to 8B, notations using “/” indicate the same signals as the signals using “N” in FIG. 2A.

FIG. 2B is a diagram showing a configuration example of a data control signal of the memory system 1 according to the embodiment. The data control signals CTRL_IN[6:0] according to the embodiment include a data instruction enable signal CTRL_IN[6], a data pattern instruction signal CTRL_IN[5:3], and a state instruction signal CTRL_IN[2:0]. FIG. 2C is a diagram showing a configuration example of a controller output signal of the memory system 1 according to the embodiment. The controller output signals CTRL_OUT[8:0] according to the embodiment include a completion signal CTRL_OUT[8] and a comparison result signal CTRL_OUT[7:0].

In FIG. 1, the data control signal CTRL_IN[6:0] and the controller output signal CTRL_OUT[8:0] are input/output between the Bypass operation host 40 and the data control circuit 18 via the Bypass I/F circuit 17. The data control signal CTRL_IN[6:0] and the controller output signal CTRL_OUT[8:0] are used to control the data input/output to the nonvolatile memory 20 during the Bypass operation, and to output the results read from the nonvolatile memory 20 to the Bypass operation host 40. The operations of the signals shown in FIGS. 2B and 2C will be described below with reference to FIGS. 5A to 8B.

As described above, in FIG. 1, the signals handled by the Bypass I/F circuit 17 are the access control signals to the nonvolatile memory 20 to which the data control signals CTRL_IN[6:0] and the controller output signals CTRL_OUT[8:0] are added.

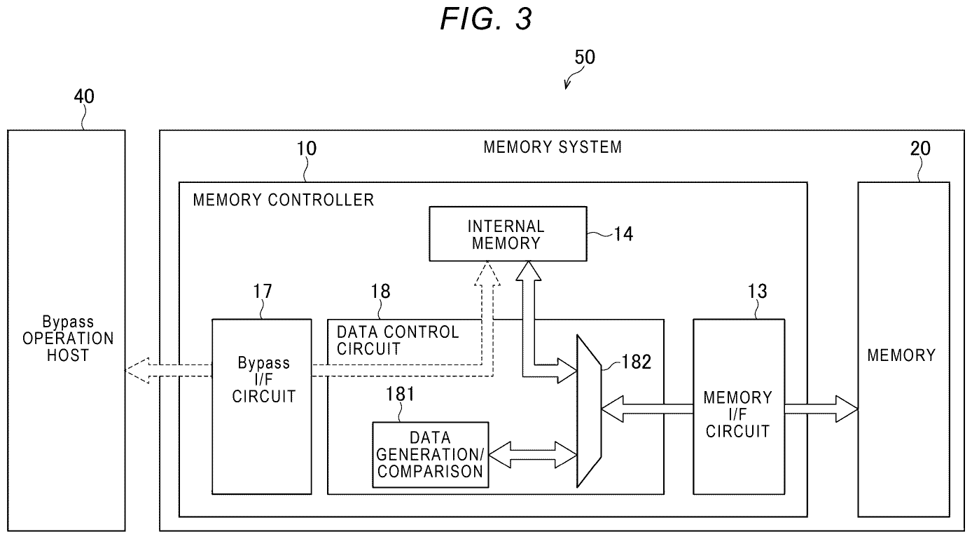

FIG. 3 is a block diagram of a main part 50 that can be used during the Bypass operation of the memory system 1 according to the embodiment. A data control circuit 18 includes a data generation/comparison circuit 181 and a selector 182. The data generation/comparison circuit 181 is connected to the selector 182. The selector 182 is connected to the memory I/F circuit 13, the internal memory 14, and the data generation/comparison circuit 181.

More specifically, the data generation/comparison circuit 181 includes a data generation circuit 181a that generates data, and an expected value comparison circuit 181b that performs expected value comparison. The data generation/comparison circuit 181 generates data to be written to the nonvolatile memory 20. Moreover, the data generation/comparison circuit 181 compares the data read from the nonvolatile memory 20 with an expected value. The selector 182 selects either the data stored in the internal memory 14 or the data generated by the data generation/comparison circuit 181, and outputs the selected data to the memory I/F circuit 13. Furthermore, the selector 182 outputs the data output from the nonvolatile memory 20 via the memory I/F circuit 13 to the selected one of the internal memory 14 and the data generation/comparison circuit 181.

In FIG. 3, solid arrows represent signal paths capable of operating at high operating frequencies, and dashed arrows represent signal paths that operate at low operating frequencies. The Bypass operation host 40, the Bypass I/F circuit 17, and parts of the data control circuit 18 and the internal memory 14 that input and output signals to and from the Bypass I/F circuit 17 (hereinafter referred to as their “first parts”) operate at low speeds. Parts of the data control circuit 18 and the internal memory 14 other than their first parts (hereinafter referred to as their “second parts”), the memory I/F circuit 13, and the nonvolatile memory 20 can operate at high speeds.

When testing the nonvolatile memory 20, the operating frequency of the Bypass I/F circuit 17, and the first parts of the data control circuit 18 and the internal memory 14 can be made lower than the maximum operating frequency of the second parts of the data control circuit 18 and the internal memory 14, the high-speed I/F circuit 15, and the controller circuit 16. By latching signals input from the Bypass operation host 40 via the Bypass I/F circuit 17 at appropriate timing relative to the skew between those signals, the signals can be correctly taken in by the memory controller 10.

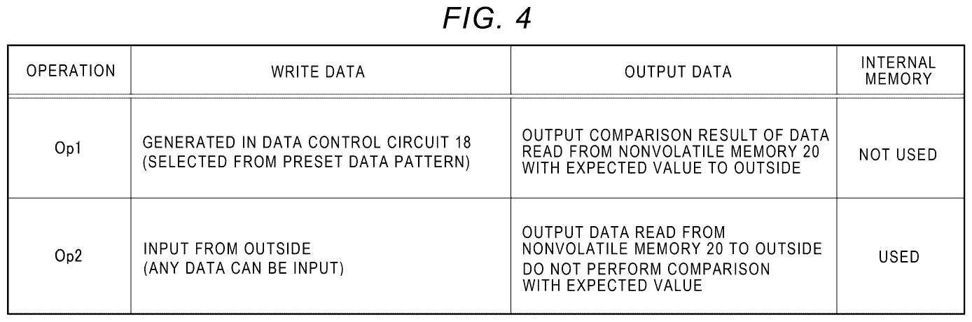

FIG. 4 is a diagram showing an example of operations that can be performed during Bypass operation of the memory system 1 according to the embodiment. The memory system 1 according to the embodiment can execute two types of operations, for example, an operation Op1 and an operation Op2, during a Bypass operation.

In operation Op1, data to be written to the nonvolatile memory 20 (hereinafter referred to as “write data”) is generated within the data control circuit 18. The data generated within the data control circuit 18 is selected from preset data patterns in accordance with the data pattern instruction signal CTRL_IN[5:3] as shown in FIG. 2B. In operation Op1, data output from the memory system 1 to the outside (hereinafter referred to as “output data”) is data indicating the comparison result of the data read from the nonvolatile memory 20 with an expected value. In operation Op1, the internal memory 14 may not be used.

In operation Op2, write data is input from outside the memory system 1 and temporarily stored in the internal memory 14. Any data can be input as the write data. Further, in operation Op2, the output data is any data read from the nonvolatile memory 20. In operation Op2, the data read from the nonvolatile memory 20 is not compared with the expected value. The data read from the nonvolatile memory 20 is temporarily stored in the internal memory 14 and then output to the outside. As described above, the internal memory 14 is used in the operation Op2.

The above-described operations Op1 and Op2 are selected by the state instruction signal CTRL_IN[2:0]. The combination of writing and reading in operations Op1 and Op2 is not limited to that shown in FIG. 4. For example, it is possible to perform an operation in which the combination of writing and reading in the operations Op1 and Op2 is changed, such as performing writing to the nonvolatile memory 20 in the operation Op1 and reading from the nonvolatile memory 20 in the operation Op2.

In the memory system 1 according to the embodiment, during Bypass operation, signals are not directly transmitted and received between the Bypass operation host 40 and the nonvolatile memory 20 in both writing to the nonvolatile memory 20 and reading from the nonvolatile memory 20. By using the data control circuit 18 and the internal memory 14 in the memory controller 10, signals can be transmitted and received between the memory controller 10 and the nonvolatile memory 20 at a high speed. This enables high-speed testing of the nonvolatile memory 20, making it possible to detect defects that occur only when the nonvolatile memory 20 is operating at a high speed.

Next, details of the operation of the memory system 1 according to the embodiment will be described with reference to a timing chart. FIGS. 5A and 5B are timing charts illustrating the write operation in operation Op1 during the Bypass operation of the memory system 1. The following timing charts show examples of a method for testing the memory system 1. Due to space limitations, the diagram is divided into FIG. 5A and FIG. 5B, but both show signal behavior during the same operation, and the time axis is common between FIG. 5A and FIG. 5B.

In FIGS. 5A and 5B, “S11” to “S15” represent steps in the write operation of operation Op1. “Data control circuit state” represents the state of the data control circuit 18, and “state (n) (n is a natural number from 1 to 7)” corresponds to the state (n) of the state instruction signal CTRL_IN[2:0] shown in FIG. 2B. “Nonvolatile memory state” represents the state of the nonvolatile memory 20.

In FIG. 5A, “CTRL_IN[6:0]” and “CTRL_OUT[8:0]” correspond to the state instruction signal CTRL_IN[6:0] shown in FIG. 2B and the controller output signal CTRL_OUT[8:0] shown in FIG. 2C, respectively. Here, the numbers written in the row of the state instruction signal CTRL_IN[2:0] represent the state (n) of the state instruction signal CTRL_IN[2:0] in FIG. 2B. For example, in step S12, “1” is written in the row of the state instruction signal CTRL_IN[2:0]. Please note that the “1” written here represents the state (1) of the state instruction signal CTRL_IN[2:0] shown in FIG. 2B, that is, the state set by the state instruction signal CTRL_IN[2:0]=000b, and does not represent the state instruction signal CTRL_IN[2:0]=001b.

In addition, in FIG. 5A, signals denoted by the symbol “(A)” are signals at the location (A) in FIG. 1 other than the state instruction signal CTRL_IN[6:0] and the controller output signal CTRL_OUT[8:0]. These signals correspond to the access control signals for the nonvolatile memory 20 input from the Bypass operation host 40. In FIG. 5B, signals denoted by the symbol “(B)” are signals at the location (B) in FIG. 1. These signals correspond to the access control signals input from the memory I/F circuit 13 to the nonvolatile memory 20.

The operation in each step of FIGS. 5A and 5B will be described below.

In the initial state, the data control circuit 18 is in a “Ready” state and is in a state capable of receiving an input signal from the Bypass operation host 40.

In step S11, a write command 61a by the signals shown in (A) of FIG. 5A is input from the Bypass operation host 40 to the memory controller 10 via the Bypass I/F circuit 17. The write command 61a is output as it is to the nonvolatile memory 20 via the memory I/F circuit 13 as a write command 61b shown in (B) of FIG. 5B.

The write command 61a will be described. Hereinafter, the state in which a signal is at H level will be represented as “1”, and the state in which a signal is at L level will be represented as “0”.

First, the command latch enable CLE is set to 1, and while inputting 80h (=1000_0000b) indicating a write command from the data input/output terminals DQ[7:0] (hereinafter referred to as “DQ”), the write enable NWE (denoted as “/WE” in FIG. 5A) is set to 1, thereby starting the input of a write command. Next, the command latch enable CLE is set to 0, and the address latch enable ALE is set to 1. Then, column addresses C1, C2 and row addresses R1, R2, R3, also called page addresses, are input in sequence from the data input/output terminal DQ while changing the write enable NWE from 0 to 1, thereby inputting addresses. Next, the address latch enable ALE is set to 0, command latch enable CLE is set to 1, and while inputting E0h indicating the command input end from the data input/output terminal DQ, write enable NWE is set to 1, thereby completing the input of the write command 61a.

When the input of the write command 61a is completed, the process proceeds to step S12 where the nonvolatile memory 20 waits for data input. In step S12, the data control signal CTRL_IN[6:0] is input from the Bypass operation host 40 to the memory controller 10 via the Bypass I/F circuit 17. By setting the state instruction signal CTRL_IN[2:0] to 000b, the state instruction is set to “state (1): data generation for nonvolatile memory output” in FIG. 2B. Then, by setting the data pattern instruction signal CTRL_IN[5:3] in a period 62 to 001b, the data pattern is set to “Random data (seed2)” in FIG. 2B. Here, the values of the data pattern instruction signal CTRL_IN[5:3] are an example, and may be another data pattern.

Then, the data instruction enable signal CTRL_IN[6] is set to 1b to enable the data instruction, thereby causing the values of the data pattern instruction signal CTRL_IN[5:3] and the state instruction signal CTRL_IN[2:0] to be taken into the data control circuit 18. At this time, the data control signal CTRL_IN[6:0] becomes 100_1000b.

In step S13, write data is input to the nonvolatile memory 20. As shown in FIG. 5A, when receiving the state instruction signal CTRL_IN[2:0]=000b, the data control circuit 18 transitions to the “state (1): data generation for nonvolatile memory output” state and generates 4K Bytes (4 KB) of write data. The Bypass operation host 40 is prohibited from inputting a command to the memory controller 10 by the signal (A) until it receives a completion signal CTRL_OUT[8]=1 from the memory controller 10, which is shown as a period 70 in FIG. 5A.

As shown in FIG. 5B, the memory controller 10 inputs the generated write data WDATA 81 to the nonvolatile memory 20 from the data input/output terminal DQ via the memory I/F circuit 13 in synchronization with the data strobe DQS. The WDATA 81 and the data strobe DQS are input to the nonvolatile memory 20 via the high-speed I/F circuit 15 at the same transmission speed as during normal operation.

The interval between inputting a write command to the nonvolatile memory 20 and starting to input write data is determined by the interval between inputting the write command 61a in step S11 and inputting the data control signal CTRL_IN[6:0] in step S12.

When the transmission of WDATA 81 to the nonvolatile memory 20 is ended, the process proceeds to step S14. In step S14, the memory controller 10 outputs the completion signal CTRL_OUT[8]=1 to the Bypass operation host 40. Moreover, the data control circuit 18 transitions to the Ready state.

In step S14, when the Bypass operation host 40 receives the completion signal CTRL_OUT[8]=1 from the memory controller 10, it becomes possible to output the next command. In step S15, a write execution command 63a shown in (A) of FIG. 5A is input from the Bypass operation host 40 to the memory controller 10 via the Bypass I/F circuit 17. The write execution command 63a is output as it is to the nonvolatile memory 20 via the memory I/F circuit 13 as a write execution command 63b shown in (B) of FIG. 5B.

The write execution commands 63a and 63b will be described. First, the command latch enable CLE is set to 1, and while inputting 10h indicating a write execution command from the data input/output terminal DQ, the write enable NWE is set to 1, thereby inputting a write execution command. When receiving the write execution command 63b, the nonvolatile memory 20 writes the WDATA 81. During the execution of the write, a ready/busy signal RnB transitions to 0. When the write is completed, the ready/busy signal RnB transitions to 1.

In FIGS. 5A and 5B, after executing the write execution command 63a, the data input/output terminal DQ is set to 70h and status read commands 64a and 64b for the nonvolatile memory 20 are executed to determine whether the writing was completed normally. However, the status read commands 64a and 64b are only examples, and other commands may be used, or no commands may be input.

By performing steps S11 to S15 described above, writing of 4 KB of data into the nonvolatile memory 20 is ended. Incidentally, some nonvolatile memories 20 have a page size of 16 KB. When the page size is 16 KB, data for one page can be written by repeating the operations shown in FIGS. 5A and 5B four times (=16 KB/4 KB) while switching between column addresses C1 and C2 within the page.

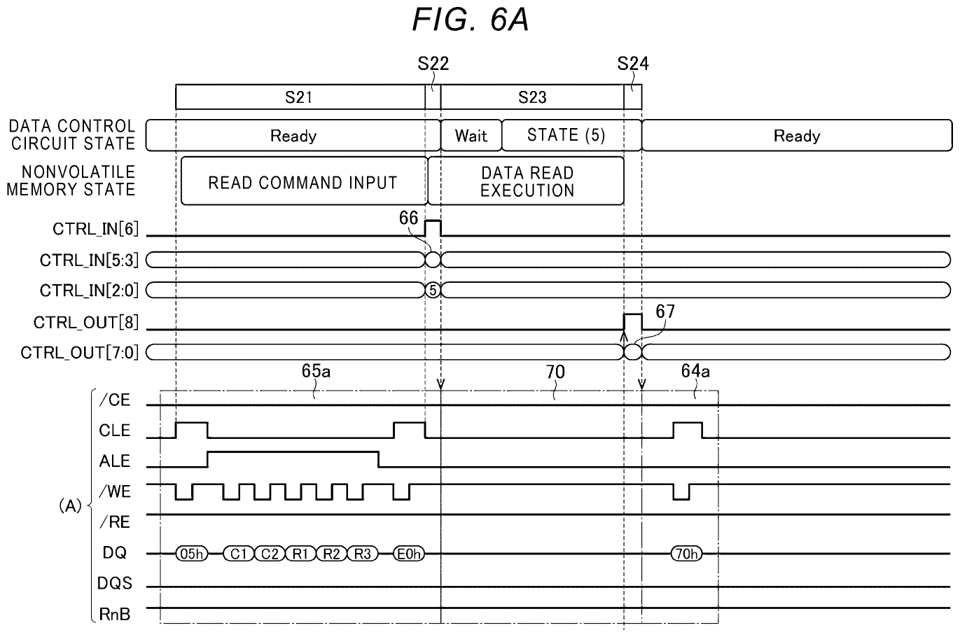

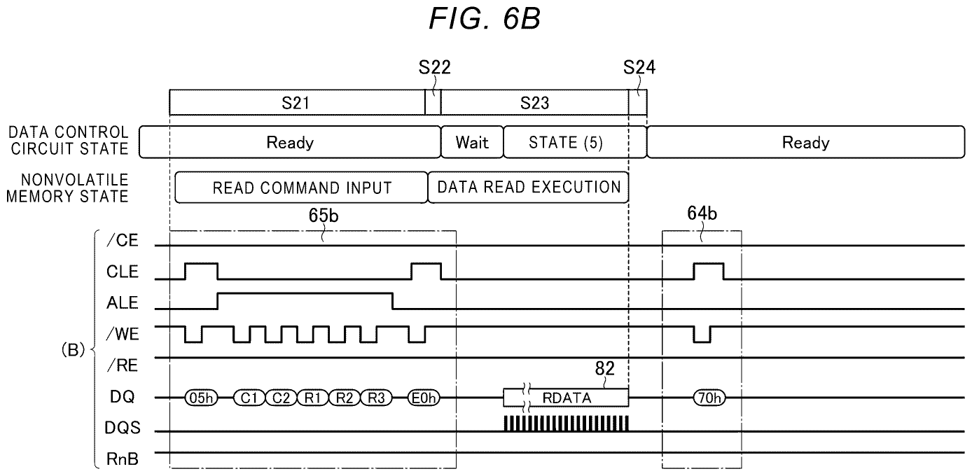

Next, details of the read operation in operation Op1 of the memory system 1 according to the embodiment will be described. FIGS. 6A and 6B are timing charts illustrating the read operation in the operation Op1 of the memory system 1. FIGS. 6A and 6B both show signal behavior during the same operation, and the time axis is common between FIG. 6A and FIG. 6B. The same parts as those in FIG. 5A and FIG. 5B are denoted by the same symbols, and the description thereof will be omitted.

In FIGS. 6A and 6B, “S21” to “S24” represent steps in the read operation of operation Op1. The operation in each step of FIGS. 6A and 6B will be described below.

In step S21, a read command 65a shown in (A) of FIG. 6A is input from the Bypass operation host 40 to the memory controller 10 via the Bypass I/F circuit 17. The read command 65a is output as it is to the nonvolatile memory 20 via the memory I/F circuit 13 as a read command 65b shown in (B) of FIG. 6B.

The read command 65a will be described. First, the command latch enable CLE is set to 1, and while inputting 05h (=0000_0101b) indicating a read command from the data input/output terminal DQ, write enable NWE (/WE) is set to 1, thereby starting the input of a read command. Next, in the same manner as described with reference to FIGS. 5A and 5B, after inputting the address, E0h indicating the command input end is input to complete the input of the read command 65a.

When the input of the read command 65a is completed, the process proceeds to step S22. In step S22, the data control signal CTRL_IN[6:0] is input from the Bypass operation host 40 to the memory controller 10 via the Bypass I/F circuit 17. By setting the state instruction signal CTRL_IN[2:0] to 100b, the state instruction is set to “state (5): nonvolatile memory data input and data generation for expected value comparison and result output” in FIG. 2B. Then, by setting the data pattern instruction signal CTRL_IN[5:3] in a period 66 to 001b, the data pattern is set to “Random data (seed2)” in FIG. 2B. The data pattern set in FIG. 6A is an example, but in order to compare the data read from the nonvolatile memory 20 with an expected value, the data pattern is set to the same as the data pattern written in advance into the nonvolatile memory 20.

Then, the data instruction enable signal CTRL_IN[6] is set to 1 to enable the data instruction, thereby causing the values of the data pattern instruction signal CTRL_IN[5:3] and the state instruction signal CTRL_IN[2:0] to be taken into the data control circuit 18. At this time, the data control signal CTRL_IN[6:0] becomes 100_1100b.

In step S23, data read from the nonvolatile memory 20 is performed. As shown in FIG. 6A, when receiving the state instruction signal CTRL_IN[2:0]=100b, the data control circuit 18 transitions to a “Wait” state of waiting for read data from the nonvolatile memory 20 as a preparation state for “state (5): nonvolatile memory data input and data generation for expected value comparison and result output”. The Bypass operation host 40 is prohibited from inputting a command to the memory controller 10 by the signal (A) until it receives a completion signal CTRL_OUT[8]=1 from the memory controller 10, which is shown as a period 70 in FIG. 6A.

The nonvolatile memory 20 executes the data read, and outputs the read data RDATA 82 to the memory controller 10 from the data input/output terminal DQ via the memory I/F circuit 13 in synchronization with the data strobe DQS, as shown in FIG. 6B. The RDATA 82 and the data strobe DQS are output from the nonvolatile memory 20 via the high-speed I/F circuit 15 at the same transmission speed as during normal operation.

When the read data is input from the nonvolatile memory 20, the data control circuit 18 transitions to a state of “state (5): nonvolatile memory data input and data generation for expected value comparison and result output”. The data control circuit 18 generates an expected value of 4 KB and compares the RDATA 82 read from the nonvolatile memory 20 with the expected value.

When the 4 KB read data RDATA 82 is read out from the nonvolatile memory 20 and the comparison of RDATA 82 with the expected value is completed, the process proceeds to step S24. In step S24, the memory controller 10 outputs a completion signal CTRL_OUT[8]=1 to the Bypass operation host 40, and outputs the comparison result signal CTRL_OUT[7:0] in a period 67. Accordingly, the data control circuit 18 transitions to the Ready state.

The comparison result signal CTRL_OUT[7:0] indicates the number of bits in which the read data does not match the expected value (hereinafter, referred to as the “number of bit flips”). When the comparison result signal CTRL_OUT[7:0] is FFh (1111_1111b), it indicates that the number of bit flips is 255 bits or more. In the present embodiment, the comparison result signal CTRL_OUT[7:0] is 8 bits long, but it is also possible to indicate the number of bit flips of 256 bits or more by increasing the bit width.

In step S24, when the Bypass operation host 40 receives the completion signal CTRL_OUT[8]=1 from the memory controller 10, it becomes possible to output the next command. In FIGS. 6A and 6B, after executing read commands 65a and 65b, the data input/output terminal DQ is set to 70h and status read commands 64a and 64b for the nonvolatile memory 20 are executed to determine whether the reading was completed normally. However, the status read commands 64a and 64b are only examples, and other commands may be used, or no commands may be input.

By performing steps S21 to S24 described above, reading of 4 KB of data from the nonvolatile memory 20 is ended. When the page size of the nonvolatile memory 20 is 16 KB, data for one page can be read by repeating the operations shown in FIGS. 6A and 6B four times while switching between column addresses C1 and C2 within the page.

The write operation and read operation in the operation Op1 of the memory system 1 according to the embodiment have been described above. Next, the write operation in operation Op2 of the memory system 1 will be described in detail.

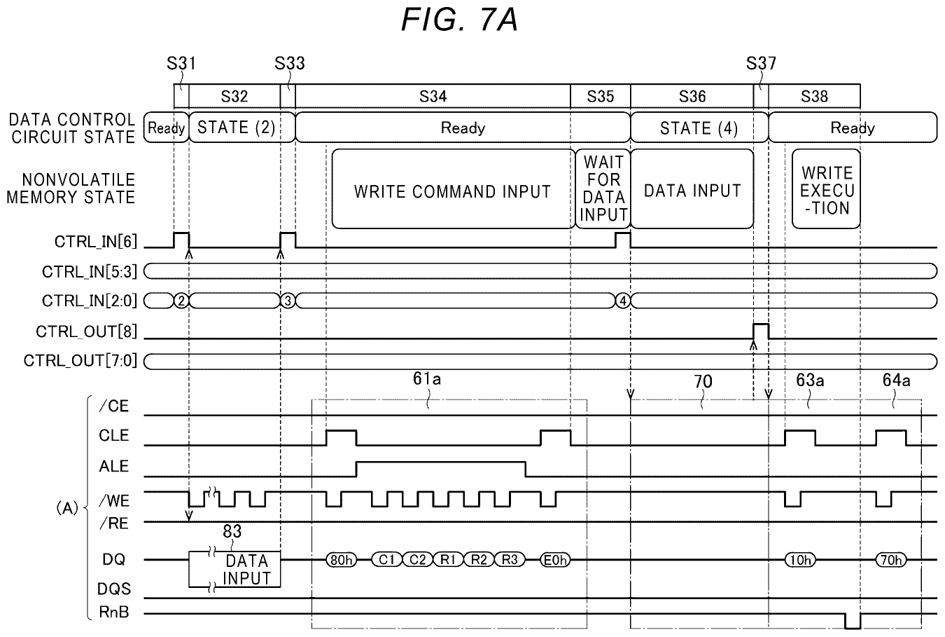

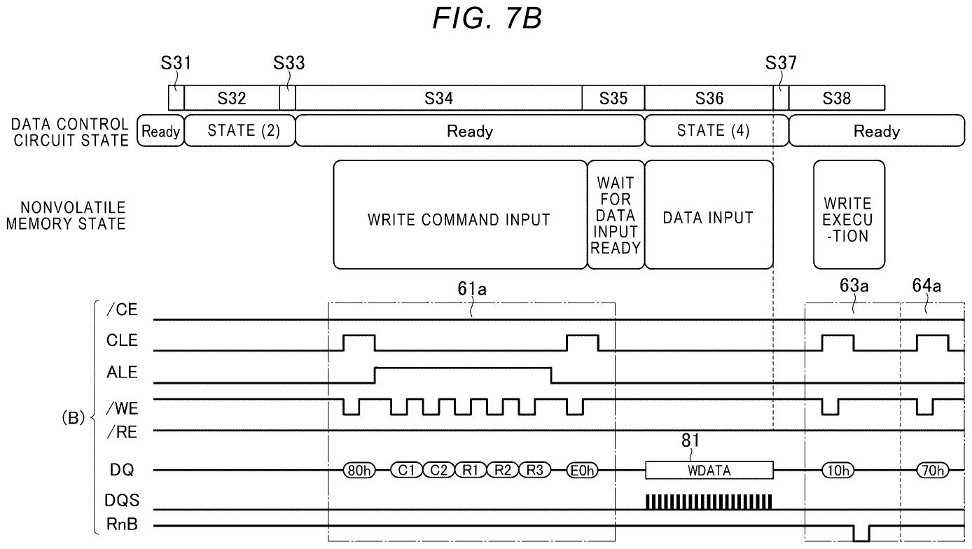

FIGS. 7A and 7B are timing charts illustrating the write operation in operation Op2 of the memory system 1. FIGS. 7A and 7B both show signal behavior during the same operation, and the time axis is common between FIG. 7A and FIG. 7B. The same parts as those in FIG. 5A and FIG. 5B are denoted by the same symbols, and the description thereof will be omitted.

In FIGS. 7A and 7B, “S31” to “S38” represent steps in the write operation of operation Op2. Compared with FIGS. 5A and 5B, FIGS. 7A and 7B are different in the following points. In FIG. 7A, data input 83 for inputting write data is performed in steps S31 to S33. Further, in FIG. 5A, in step S12 prior to step S13 of inputting data into nonvolatile memory 20, state instruction signal CTRL_IN[2:0] is set to state (1), whereas in FIG. 7A, in step S35, state instruction signal CTRL_IN[2:0] is set to state (4). The operation in each step of FIGS. 7A and 7B will be described below.

In step S31, the data control signal CTRL_IN[6:0] is input from the Bypass operation host 40 to the memory controller 10 via the Bypass I/F circuit 17. By setting the state instruction signal CTRL_IN[2:0] to 001b, the state instruction is set to “state (2): host data input for internal memory write”. As will be described later, in operation Op2, the data pattern instruction signal CTRL_IN[5:3] becomes “Don't care”. As an example, the data pattern instruction signal CTRL_IN[5:3]=000b. Then, the data instruction enable signal CTRL_IN[6]=1 causes the value of the state instruction signal CTRL_IN[2:0] to be taken into the memory controller 10. At this time, the data control signal CTRL_IN[6:0] becomes 100_0001b.

When receiving the state instruction signal CTRL_IN[2:0]=001b, the data control circuit 18 transitions to state (2). This makes it possible to input write data into the internal memory 14.

In step S32, data input 83 of the write data is performed in synchronization with the toggling of the write enable NWE (/WE), from the Bypass operation host 40 through the data input/output terminal DQ. Thus, the write data is input to the memory controller 10. The input write data is written into the internal memory 14 via the data control circuit 18 and temporarily stored therein.

When writing of the write data to the internal memory 14 is completed, in step S33, the data control signal CTRL_IN[6:0] is input from the Bypass operation host 40 to the memory controller 10 via the Bypass I/F circuit 17. By setting the state instruction signal CTRL_IN[2:0] to 010b, the state instruction is set to “state (3): host data input completed” in FIG. 2B. Then, the data instruction enable signal CTRL_IN[6]=1 causes the value of the state instruction signal CTRL_IN[2:0] to be taken into the memory controller 10. At this time, the data control signal CTRL_IN[6:0] becomes 100_0010b. When receiving the state instruction signal CTRL_IN[2:0]=010b, the data control circuit 18 ends writing the write data to the internal memory 14 and transitions to the Ready state.

In step S34, the write command 61a shown in (A) of FIG. 7A is input from the Bypass operation host 40 to the memory controller 10 via the Bypass I/F circuit 17. The write command 61a is output as it is to the nonvolatile memory 20 via the memory I/F circuit 13 as a write command 61b shown in (B) of FIG. 7B. The write commands 61a and 61b are similar to those described with reference to FIGS. 5A and 5B, and therefore a description thereof will be omitted.

When the input of the write command 61a is completed, the process proceeds to step S35 where the nonvolatile memory 20 waits for data input. In step S35, the data control signal CTRL_IN[6:0] is input from the Bypass operation host 40 to the memory controller 10 via the Bypass I/F circuit 17. By setting the state instruction signal CTRL_IN[2:0] to 011b, the state instruction is set to “state (4): internal memory read for nonvolatile memory output” in FIG. 2B. By selecting state (4), it is instructed that any data is to be handled, and the data pattern instruction signal CTRL_IN[5:3] becomes “Don't care”. Then, the data instruction enable signal CTRL_IN[6]=1 causes the value of the state instruction signal CTRL_IN[2:0] to be taken into the memory controller 10. At this time, the data control signal CTRL_IN[6:0] becomes 100_0011b.

In step S36, when receiving the state instruction signal CTRL_IN[2:0]=011b, the data control circuit 18 transitions to the state “state (4): internal memory read for nonvolatile memory output”. As shown in FIG. 7B, the memory controller 10 inputs WDATA 81, which is write data read from the internal memory 14, to the nonvolatile memory 20 via the memory I/F circuit 13 from the data input/output terminal DQ in synchronization with the data strobe DQS. The WDATA 81 and the data strobe DQS are input to the nonvolatile memory 20 via the high-speed I/F circuit 15 at the same transmission speed as during normal operation.

The interval between inputting a write command to the nonvolatile memory 20 and starting to input write data is determined by the interval between inputting the write command 61a in step S34 and inputting the data control signal CTRL_IN[6:0] in step S35. The Bypass operation host 40 is prohibited from inputting a command to the memory controller 10 by the signal (A) until it receives a completion signal CTRL_OUT[8]=1 from the memory controller 10, which is shown as a period 70 in FIG. 7A.

When the transmission of the write data WDATA 81 to the nonvolatile memory 20 is ended, the process proceeds to step S37. In step S37, the memory controller 10 outputs the completion signal CTRL_OUT[8]=1 to the Bypass operation host 40. Moreover, the data control circuit 18 transitions to the Ready state.

In step S37, when the Bypass operation host 40 receives the completion signal CTRL_OUT[8]=1 from the memory controller 10, it becomes possible to output the next command. In step S38, the write execution command 63a shown in (A) of FIG. 7A is input from the Bypass operation host 40 to the memory controller 10 via the Bypass I/F circuit 17. The write execution command 63a is output as it is to the nonvolatile memory 20 via the memory I/F circuit 13 as a write execution command 63b shown in (B) of FIG. 7B. The write execution commands 63a and 63b are similar to those described with reference to FIGS. 5A and 5B, and therefore a description thereof will be omitted.

In FIGS. 7A and 7B, after the write execution command 63a is executed, status read commands 64a and 64b of the nonvolatile memory 20 are executed to determine whether the writing was completed normally. However, the status read commands 64a and 64b are only examples, and other commands may be used, or no commands may be input.

By performing steps S31 to S38 described above, writing of 4 KB of data into the nonvolatile memory 20 is ended. In the write operation of operation Op2 described above, any write data from the Bypass operation host 40 is temporarily stored in the internal memory 14 at a low speed, and then written into the nonvolatile memory 20 at a high speed. According to the write operation of operation Op2, any write data can be written into the nonvolatile memory 20 at a high speed. When the page size of the nonvolatile memory 20 is 16 KB, data for one page can be written by repeating the operations shown in FIGS. 7A and 7B four times while switching between column addresses C1 and C2 within the page.

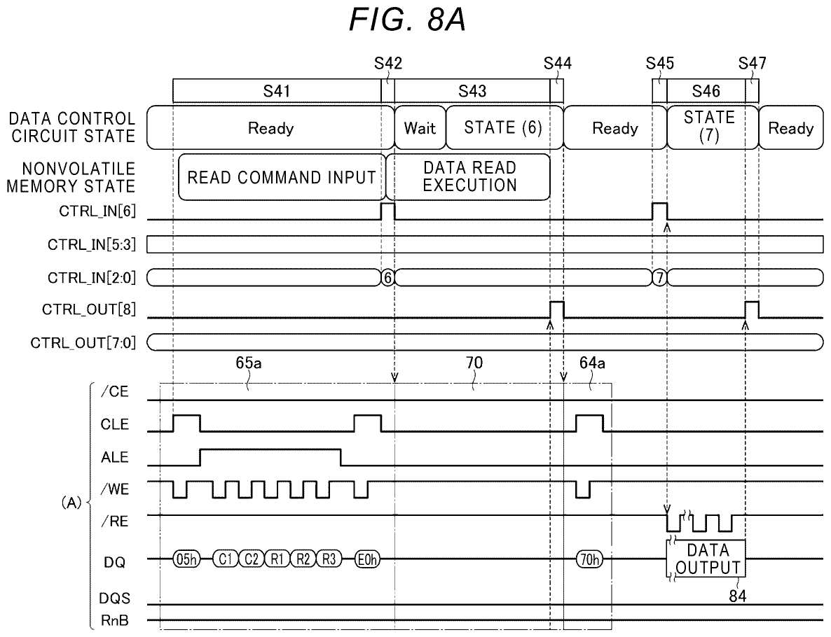

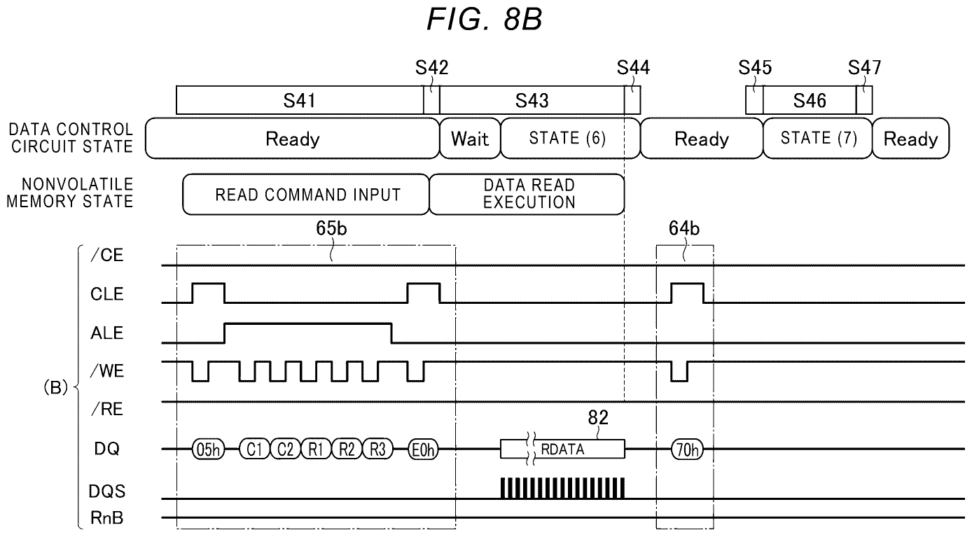

FIGS. 8A and 8B are timing charts illustrating the read operation in operation Op2 of the memory system 1. FIGS. 8A and 8B both show signal behavior during the same operation, and the time axis is common between FIG. 8A and FIG. 8B. The same parts as those in FIG. 6A and FIG. 6B are denoted by the same symbols, and the description thereof will be omitted.

In FIGS. 8A and 8B, “S41” to “S47” represent steps in the read operation of operation Op2. Compared with FIGS. 6A and 6B, FIGS. 8A and 8B are different in the following points. In FIG. 6A, in step S22 prior to step S23 of reading data from the nonvolatile memory 20, the state instruction signal CTRL_IN[2:0] is set to state (5). In contrast, in FIG. 8A, the state instruction signal CTRL_IN[2:0] is set to state (6) in step S42. In FIG. 8A, data output 84 for outputting read data is performed in steps S45 to S47. The operation in each step of FIGS. 8A and 8B will be described below.

In step S41, the read command 65a shown in (A) of FIG. 8A is input from the Bypass operation host 40 to the memory controller 10 via the Bypass I/F circuit 17. The read command 65a is output as it is to the nonvolatile memory 20 via the memory I/F circuit 13 as a read command 65b shown in (B) of FIG. 8B. The read command 65a is similar to that described with reference to FIG. 6A, and therefore a description thereof will be omitted.

When the input of the read command 65a is completed, the process proceeds to step S42. In step S42, the data control signal CTRL_IN[6:0] is input from the Bypass operation host 40 to the memory controller 10 via the Bypass I/F circuit 17. By setting the state instruction signal CTRL_IN[2:0] to 101b, the state instruction is set to “state (6): nonvolatile memory data input for internal memory writing” in FIG. 2B. By selecting state (6), it is instructed that any data is to be handled, and the data pattern instruction signal CTRL_IN[5:3] becomes “Don't care”.

Then, the data instruction enable signal CTRL_IN[6] is set to 1 to enable the data instruction, thereby causing the value of the state instruction signal CTRL_IN[2:0] to be taken into the data control circuit 18. At this time, the data control signal CTRL_IN[6:0] becomes 100_0101b.

In step S43, data reading from the nonvolatile memory 20 is performed. As shown in FIG. 8A, when receiving the state instruction signal CTRL_IN[2:0]=101b, the data control circuit 18 transitions to a Wait state in which it waits for read data from the nonvolatile memory 20 as a preparation state for “state (6): nonvolatile memory data input for internal memory writing”. The Bypass operation host 40 is prohibited from inputting a command to the memory controller 10 by the signal (A) until it receives a completion signal CTRL_OUT[8]=1 from the memory controller 10, which is shown as a period 70 in FIG. 8A.

The nonvolatile memory 20 executes the data reading, and outputs the read data RDATA 82 to the memory controller 10 from the data input/output terminal DQ via the memory I/F circuit 13 in synchronization with the data strobe DQS, as shown in FIG. 8B. The RDATA 82 and the data strobe DQS are output from the nonvolatile memory 20 at the same transmission speed as during normal operation via the high-speed I/F circuit 15.

When read data is input from the nonvolatile memory 20, the data control circuit 18 transitions to the state of “state (6): nonvolatile memory data input for internal memory writing”. The data control circuit 18 writes the RDATA 82, which is data read from the nonvolatile memory 20, into the internal memory 14 for temporary storage.

When the entire 4 KB of RDATA 82 is read from the nonvolatile memory 20, the process proceeds to step S44. In step S44, the memory controller 10 outputs the completion signal CTRL_OUT[8]=1 to the Bypass operation host 40. Accordingly, the data control circuit 18 transitions to the Ready state.

In step S44, when the Bypass operation host 40 receives the completion signal CTRL_OUT[8]=1 from the memory controller 10, it becomes possible to output the next command. In FIGS. 8A and 8B, after the read commands 65a and 65b are executed, status read commands 64a and 64b of the nonvolatile memory 20 are executed to determine whether the reading was completed normally. However, the status read commands 64a and 64b are only an example, and no command may be input.

In step S45, the data control signal CTRL_IN[6:0] is input from the Bypass operation host 40 to the memory controller 10 via the Bypass I/F circuit 17. By setting the state instruction signal CTRL_IN[2:0] to 110b, the state instruction is set to “state (7): internal memory read for host output”. Then, the data instruction enable signal CTRL_IN[6]=1 causes the state instruction signal CTRL_IN[2:0]=110b that specifies the state (7) to be taken into the memory controller 10. At this time, the data control signal CTRL_IN[6:0] becomes 100_0110b. When receiving the state instruction signal CTRL_IN[2:0]=110b, the data control circuit 18 transitions to the state of “state (7): internal memory read for host output”. This makes it possible to output read data from the internal memory 14.

In step S46, in synchronization with the toggling of the read enable NRE (denoted as “/RE” in FIG. 8A), the read data read from the internal memory 14 is output to the Bypass operation host 40 through the data input/output terminal DQ.

When reading of the read data from the internal memory 14 is completed, the memory controller 10 outputs the completion signal CTRL_OUT[8]=1 to the Bypass operation host 40 in step S47. Accordingly, the data control circuit 18 transitions to the Ready state. In step S47, when the Bypass operation host 40 receives the completion signal CTRL_OUT[8]=1 from the memory controller 10, it becomes possible to output the next command.

By performing steps S41 to S47 described above, reading of 4 KB of data from the nonvolatile memory 20 is ended. In the read operation of the operation Op2 described above, any read data from the nonvolatile memory 20 is temporarily stored in the internal memory 14 at a high speed, and then output to the Bypass operation host 40 at a low speed. According to the read operation of operation Op2, any read data can be read from the nonvolatile memory 20 at a high speed. When the page size of the nonvolatile memory 20 is 16 KB, data for one page can be read by repeating the operations shown in FIGS. 8A and 8B four times while switching between column addresses C1 and C2 within the page.

The nonvolatile memory 20 of the memory system 1 may be capable of performing an erasing operation in addition to data write operation and read operation. When the nonvolatile memory 20 is capable of performing an erasing operation, during Bypass operation, the nonvolatile memory 20 can be caused to perform an erase operation, by inputting an erasing command from the Bypass operation host 40 to the memory system 1 using the access control signal shown in FIG. 2A.

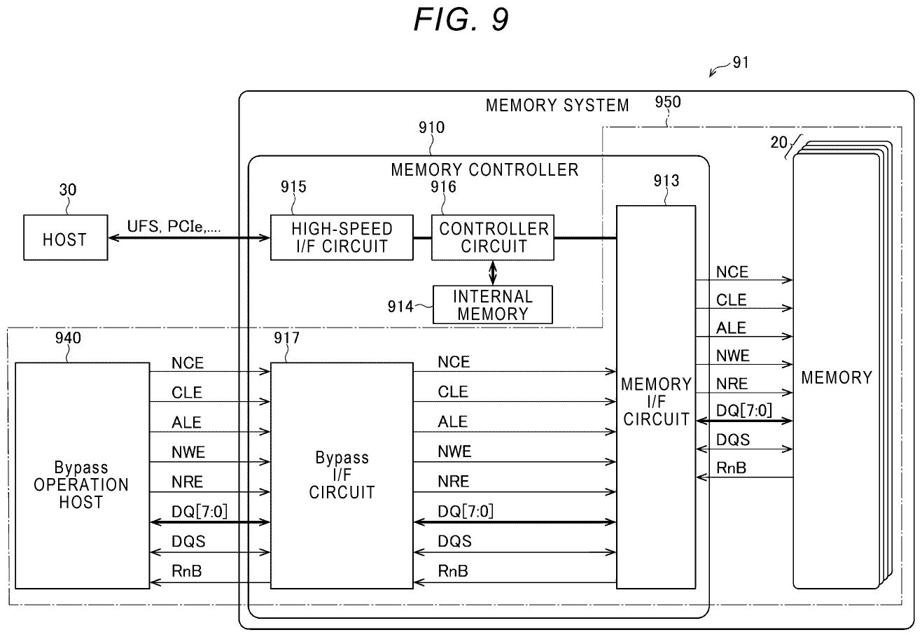

Here, in order to facilitate understanding of the features of the embodiments of the present disclosure, a memory system of a comparative example will be described. FIG. 9 is a block diagram of a memory system 91 of the comparative example. The same parts as those in FIG. 1 are denoted by the same symbols, and the description thereof will be omitted.

The memory system 91 of the comparative example in FIG. 9 includes a high-speed I/F circuit 915, a controller circuit 916, a Bypass I/F circuit 917, a memory I/F circuit 913, and an internal memory 914. During normal operation of the memory system 91, the memory system 91 is connected to the host 30 via the high-speed I/F circuit 915. When testing the memory system 91, the memory system 91 is connected to a Bypass operation host 940 via a Bypass I/F circuit 917. The memory system 91 can switch between normal operation using the high-speed I/F circuit 915 and Bypass operation using the Bypass I/F circuit 917 by setting a register inside the memory controller 910, or setting by applying a voltage to a dedicated terminal when the power is turned on.

Compared with FIG. 1, FIG. 9 is different in the following points. In FIG. 1, the memory controller 10 includes a data control circuit 18. In addition, in FIG. 1, a data control signal CTRL_IN[6:0] and a controller output signal CTRL_OUT[8:0] are input/output between the Bypass operation host 40 and the Bypass I/F circuit 17 and data control circuit 18. In contrast, in FIG. 9, the memory controller 910 does not include the data control circuit 18. In addition, in FIG. 9, the data control signal CTRL_IN[6:0] and the controller output signal CTRL_OUT[8:0] are not input/output between the Bypass operation host 940 and the Bypass I/F circuit 917.

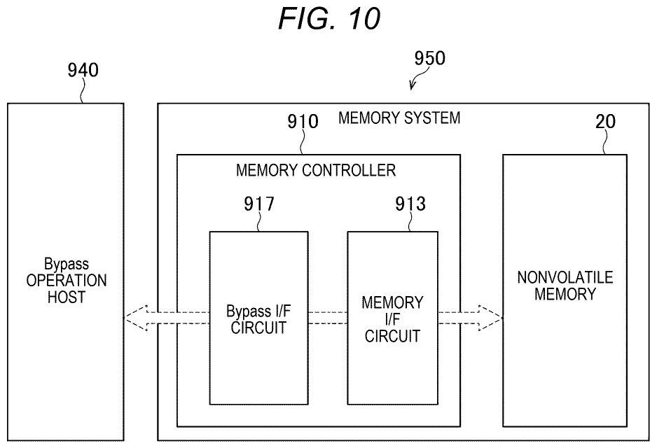

FIG. 10 is a block diagram of a main part 950 that can be used during Bypass operation of the memory system 91 of the comparative example. The same parts as those in FIG. 3 are denoted by the same symbols, and the description thereof will be omitted. In FIG. 10, the dashed arrows represent signal paths that operate at the lower operating frequency. The parts that input and output signals to and from the Bypass operation host 940, the Bypass I/F circuit 917, and the memory I/F circuit 13 operate at a low speed.

The Bypass I/F circuit 917 is connected to the nonvolatile memory 20 via the memory I/F circuit 913 without going through the controller circuit 916. Therefore, any command for controlling the nonvolatile memory 20 can be directly output from the Bypass operation host 940 to the nonvolatile memory 20 and executed. However, as described above, there is a skew between the signals input from the Bypass operation host 940 via the Bypass I/F circuit 917. Therefore, in order to properly latch the signal inside the memory controller 910, the signal needs to be input at a low frequency, and the test of the nonvolatile memory 20 is performed at a low speed. In the memory system 91 of the comparative example, the test is performed at a low speed, and therefore defects that occur only when the nonvolatile memory 20 operates at a high speed cannot be detected.

In comparison with the comparative example shown in FIG. 9, the memory system 1 according to the embodiment shown in FIG. 1 includes a data control circuit 18, and data can be controlled by the data control signal CTRL_IN[6:0] and the controller output signal CTRL_OUT[8:0]. The parts of the data control circuit 18 and the internal memory 14 of the memory system 1 other than the parts that input and output signals to and from the Bypass I/F circuit 17 can operate at a high speed. In the memory system 1, during Bypass operation, by using the data control circuit 18 and the internal memory 14, signals can be transmitted and received between the memory controller 10 and the nonvolatile memory 20 at a high speed. This enables high-speed testing of the nonvolatile memory 20, making it possible to detect defects that occur only when the nonvolatile memory 20 is operating at a high speed.

### Effects of Embodiment

According to the memory system 1 of the embodiment, during Bypass operation, by using the data control circuit 18 and the internal memory 14, signals can be transmitted and received between the memory controller 10 and the nonvolatile memory 20 at a high speed. This enables high-speed testing of the nonvolatile memory 20, making it possible to detect defects that occur only when the nonvolatile memory 20 is operating at a high speed.

According to the memory system 1 according to the embodiment, during a Bypass operation, a desired operation can be selected from, for example, operation Op1 and operation Op2 and executed. In operation Op1, data to be written to the nonvolatile memory 20 can be generated within the data control circuit 18, and the comparison result of the data read from the nonvolatile memory 20 and an expected value can be output to the outside. In operation Op2, any data to be written to the nonvolatile memory 20 can be input from outside the memory system 1, and any data read from the nonvolatile memory 20 can be output to the outside. As described above, a high-speed test can be performed according to the purpose of the test and the test environment.

### Other Embodiments

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

For example, an example was shown in which two types of operations, that is, operation Op1 and operation Op2, can be executed in the memory system 1 according to the embodiment. However, the memory system 1 is not limited to this, and may be configured to be capable of executing, for example, either operation Op1 or operation Op2, and not to include the operation specification for the other operation. Since the operation specification for the other operation is not included, the circuit size of the data control circuit 18 or the internal memory 14 can be reduced, and the chip size of the memory controller 10 can be reduced. For example, when the operation specification of operation Op2 is not implemented, the internal memory 14 may not be used, and the circuit size of the internal memory 14 may be reduced.

Further, for example, in the description of the memory system 1 according to the above embodiment, an example was shown in which a Bypass operation using the data control circuit 18 is used in testing or defect analysis of the memory system 1. However, the use example of the Bypass operation using the data control circuit 18 is not limited to this example. For example, when a failure occurs in the controller circuit 16 or the like after the memory system 1 is shipped, causing some of the functions of the memory system 1 to not operate, the user's system developer may use a Bypass operation to directly access the nonvolatile memory 20.

Furthermore, for example, in the memory system 1 according to the embodiment, an example in which a NAND flash memory is used as the nonvolatile memory 20 is shown. However, the nonvolatile memory 20 is not limited to a semiconductor memory, and may be various storage media other than a semiconductor memory.

What is claimed is:

1. A memory system comprising:
a nonvolatile memory; and
a controller operatively coupled to the nonvolatile memory, wherein
the controller includes:
a first input/output circuit configured to receive input of an access control signal for accessing the nonvolatile memory and a data control signal and output a signal based on data read from the nonvolatile memory; and
a data control circuit configured to control data to be input to the nonvolatile memory and data to be output from the nonvolatile memory, based on the data control signal input from the first input/output circuit.

2. The memory system according to claim 1, wherein
the data control signal includes:
a data pattern instruction signal configured for instructing a data pattern to be input to and output from the nonvolatile memory; and
a state instruction signal configured for instructing a state of input/output for the nonvolatile memory.

3. The memory system according to claim 1, wherein
the data control circuit includes a data generation circuit configured to generate write data to be input to the nonvolatile memory, based on the data control signal.

4. The memory system according to claim 3, wherein
the controller is configured to combine the access control signal input from the first input/output circuit with the write data generated by the data generation circuit, based on the data control signal, and input the combined data to the nonvolatile memory.

5. The memory system according to claim 4, wherein
the controller is configured to input the write data to the nonvolatile memory at an operating frequency higher than an operating frequency of the first input/output circuit.

6. The memory system according to claim 1, wherein
the data control circuit includes an expected value comparison circuit configured to compare read data output from the nonvolatile memory with an expected value, based on the data control signal.

7. The memory system according to claim 6, wherein
the controller is configured to output an output of the expected value comparison circuit from the first input/output circuit, based on the data control signal.

8. The memory system according to claim 7, wherein
the controller is configured to cause the nonvolatile memory to execute a read operation at an operating frequency higher than an operating frequency of the first input/output circuit.

9. The memory system according to claim 1, wherein
the controller further includes an internal memory disposed inside the controller, and
the internal memory is configured to store write data input from the first input/output circuit and to be input to the nonvolatile memory.

10. The memory system according to claim 9, wherein
the controller is configured to combine the access control signal input from the first input/output circuit with the write data stored in the internal memory, based on the data control signal, and input the combined data to the nonvolatile memory.

11. The memory system according to claim 1, wherein
the controller further includes an internal memory disposed within the controller, and
the internal memory is configured to store read data output from the nonvolatile memory.

12. The memory system according to claim 11, wherein
the controller is configured to output the read data stored in the internal memory from the first input/output circuit, based on the data control signal.

13. The memory system according to claim 1, wherein
the controller further includes:
a second input/output circuit configured to perform input and output of a signal for controlling a normal operation of the nonvolatile memory; and
a first control circuit configured to control a normal operation of the nonvolatile memory, based on a signal input from the second input/output circuit,
the first input/output circuit and the data control circuit are operable during testing of the nonvolatile memory, and
the second input/output circuit and the first control circuit are operable during the normal operation of the nonvolatile memory.

14. The memory system according to claim 13, wherein
the data control circuit and an internal memory of the controller each include a first part configured to perform inputting and outputting a signal to and from the first input/output circuit, and a second part other than the first part, and
an operating frequency of the first parts of the data control circuit and the internal memory during testing of the nonvolatile memory is lower than a maximum operating frequency of the second parts of the data control circuit and the internal memory.

15. The memory system according to claim 1, wherein
the nonvolatile memory is a NAND flash memory.

16. The memory system according to claim 15, wherein
the NAND flash memory and the controller are formed as a multi-chip package (MCP).

17. A method for testing a memory system, comprising:
inputting a write command to a memory system according to an access control signal;
inputting a data control signal to the memory system to input data to a nonvolatile memory in a controller;
generating and inputting the input data to the nonvolatile memory; and
causing the nonvolatile memory to execute writing of the input data.

18. The method according to claim 17, comprising:
inputting a read command to the memory system according to the access control signal;
inputting the data control signal to the memory system to set an expected value in the controller;
comparing data read from the nonvolatile memory with the expected value to generate a comparison result; and
outputting the comparison result from the memory system.

19. The method according to claim 18, comprising:
inputting the data control signal to the memory system to transition to a state allowing data to be input to an internal memory of the controller;
inputting the data to the internal memory;
inputting the data control signal to the memory system to end the state;
inputting the write command to the memory system according to the access control signal;
inputting the data control signal to the memory system to set reading of data to be input to the nonvolatile memory from the internal memory;
reading data to be input to the nonvolatile memory from the internal memory and inputting the data to the nonvolatile memory; and
causing the nonvolatile memory to execute writing of the data.

20. The method according to claim 18, comprising:
inputting the read command to the memory system according to the access control signal;
inputting the data control signal to the memory system to input the read data to the internal memory;
inputting the data control signal to the memory system to transition to a state allowing the read data input to the internal memory to be output;
outputting, from the memory system, the read data input to the internal memory; and
inputting the data control signal to the memory system to end the state.
